(19) United States
(12) Patent Application Publication
(10) Pub. No.: US 2025/0063825 A1
(43) Pub. Date: Feb. 20, 2025

(54) INTEGRATED CIRCUIT DEVICES INCLUDING DISCHARGING PATH AND METHODS OF FORMING THE SAME

(71) Applicant: Samsung Electronics Co., Ltd., Suwon-si (KR)

(72) Inventors: JAEHONG LEE, Latham, NY (US); WONHYUK HONG, Clifton Park, NY (US); KANG-ILL SEO, Springfield, VA (US)

(21) Appl. No.: 18/735,681

(22) Filed: Jun. 6, 2024

Related U.S. Application Data
(60) Provisional application No. 63/519,293, filed on Aug. 14, 2023.

(51) Int. Cl. H01L 27/02; H01L 21/822; H01L 21/8238; H01L 23/528; H01L 27/06; H01L 27/092; H01L 29/06; H01L 29/08; H01L 29/423; H01L 29/66; H01L 29/775; H01L 29/786

(52) U.S. Cl. CPC H01L 27/0255; H01L 21/8221; H01L 21/823807; H01L 21/823814; H01L 21/823871; H01L 23/5283; H01L 27/0688; H01L 27/0922; H01L 29/0673; H01L 29/0847; H01L 29/42392; H01L 29/66439; H01L 29/775; H01L 29/78696

(57) ABSTRACT

Integrated circuit devices and methods of forming the same. As an example, an integrated circuit device may include a first substrate; a first transistor structure on the substrate; a second transistor structure stacked in a vertical direction on the first transistor structure; an isolation layer between the first transistor structure and the second transistor structure in the vertical direction; a diode structure on the first substrate and adjacent to the first transistor structure in a horizontal direction; and a second substrate on the second transistor structure in the vertical direction. The diode structure may be part of a discharging path between a gate electrode of the second transistor structure and the second substrate. The discharging path may extend through the isolation layer.

### CROSS-REFERENCE TO RELATED APPLICATION

This application claims priority to U.S. Provisional Application Ser. No. 63/519,293 entitled “INTEGRATED CIRCUIT DEVICES INCLUDING DISCHARGING PATH AND METHODS OF FORMING THE SAME,” filed in the United States Patent and Trademark Office on Aug. 14, 2023, and the entire contents of the above-identified application are incorporated by reference herein in its entirety.

### BACKGROUND

The present disclosure generally relates to the field of integrated circuit devices and, more particularly, to three-dimensional integrated circuit devices that include stacked transistors.

Various structures of an integrated circuit device including stacked transistors and methods of forming the same have been proposed for secure isolation between elements of stacked transistors (e.g., stacked source/drain regions or stacked gate electrodes).

### SUMMARY

According to some embodiments of the present inventive concepts, an integrated circuit device may include: a first substrate; a first transistor structure on the first substrate; a second transistor structure stacked in a vertical direction on the first transistor structure; a second substrate stacked in a vertical direction on the second transistor structure; an isolation layer between the first transistor structure and the second transistor structure in the vertical direction; and a discharging path between a gate electrode of the second transistor structure and the second substrate, the discharging path including a diode structure on the first substrate.

According to some embodiments of the present inventive concepts, an integrated circuit device may include a first substrate; and a stacked structure comprising: a first transistor structure on the first substrate and comprising a first source/drain region having a first conductivity type; and a second transistor structure stacked in a vertical direction on the first transistor structure, the second transistor structure comprising a second source/drain region having a second conductivity type that is opposite from the first conductivity type. The integrated circuit device may include an isolation layer between the first transistor structure and the second transistor structure in the vertical direction; a second substrate on an opposite side of the stacked structure from the first substrate; and a discharging path between a gate electrode of the second transistor structure and the second substrate, the discharging path comprising a diode structure.

According to some embodiments of the present inventive concepts, a method of forming an integrated circuit device may include: forming a stacked structure on a first substrate, the stacked structure comprising lower channel layers, upper channel layers, and an isolation layer between the lower and upper channel layers; forming source/drain regions in the stacked structure, the source/drain regions comprising lower source/drain regions and upper source/drain regions; forming a diode structure in the stacked structure, the diode structure including a first diode region and a second diode region; forming gate structures in the stacked structure, the gate structures comprising lower gate structures and upper gate structures; providing a second substrate on an opposite side of the stacked structure from the first substrate; and providing a discharging path between an upper gate structure and the second substrate, the discharging path including the diode structure.

The present disclosure is not limited to the above-described embodiments and inventive concepts, and other embodiments and inventive concepts are provided in the figures and the detailed description thereof.

### BRIEF DESCRIPTION OF THE DRAWINGS

FIG. 1 is a layout of an integrated circuit device according to some embodiments.

FIGS. 2A and 2B are cross-sectional views of an integrated circuit device taken along the line A-A′ and the line B-B′, respectively, in FIG. 1 according to some embodiments.

FIG. 3 is a schematic diagram showing a discharging path of the integrated circuit device of FIGS. 1, 2A, and 2B, according to some embodiments.

FIG. 4 is a circuit diagram showing a discharging path of the integrated circuit device of FIGS. 1, 2A, and 2B, according to some embodiments.

FIG. 5 is a cross-sectional view of an integrated circuit device taken along the line B-B′ in FIG. 1 according to some embodiments.

FIG. 6 is a schematic diagram showing a discharging path of the integrated circuit device of FIG. 5 according to some embodiments

FIG. 7 is a cross-sectional view of an integrated circuit device taken along the line B-B′ in FIG. 1 according to some embodiments.

FIG. 8 is a cross-sectional view of an integrated circuit device taken along the line B-B′ in FIG. 1 according to some embodiments.

FIG. 9 is a flowchart showing operations in a method of forming an integrated circuit device according to some embodiments.

FIGS. 10, 11, 12A, 12B, 13-16, 17A, 17B, 17C, 18, and 19 are cross-sectional views of intermediate steps of a method of forming the integrated circuit device of FIG. 1

Like reference numerals may refer to corresponding parts throughout the drawings.

### DETAILED DESCRIPTION

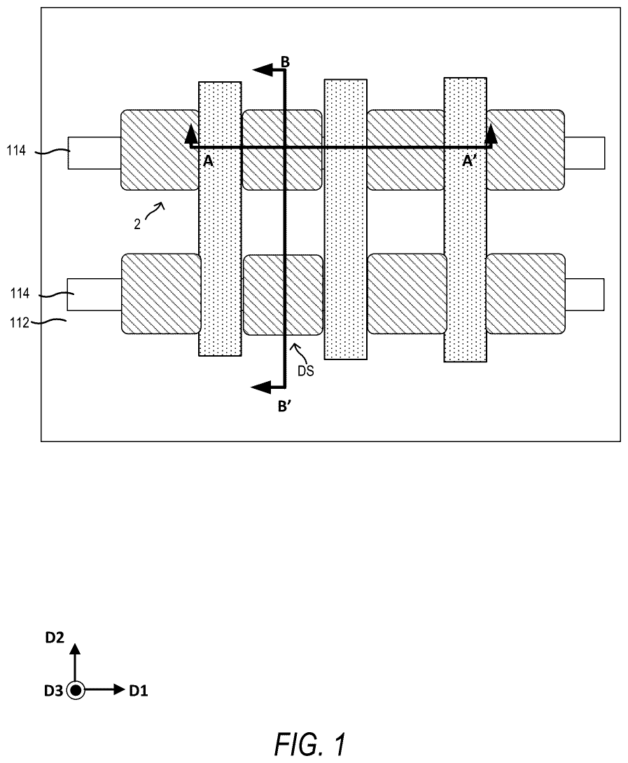

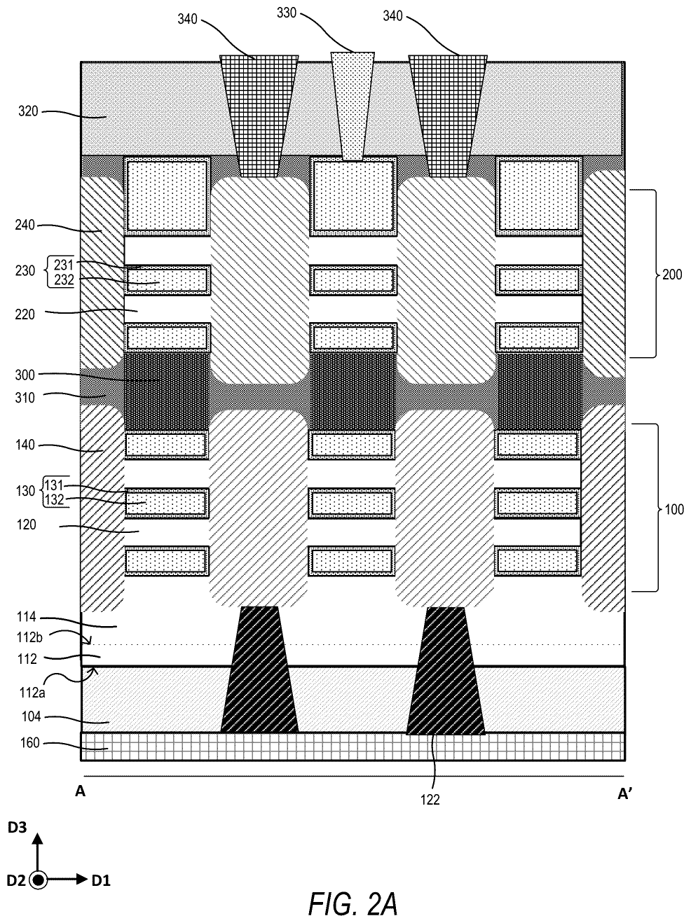

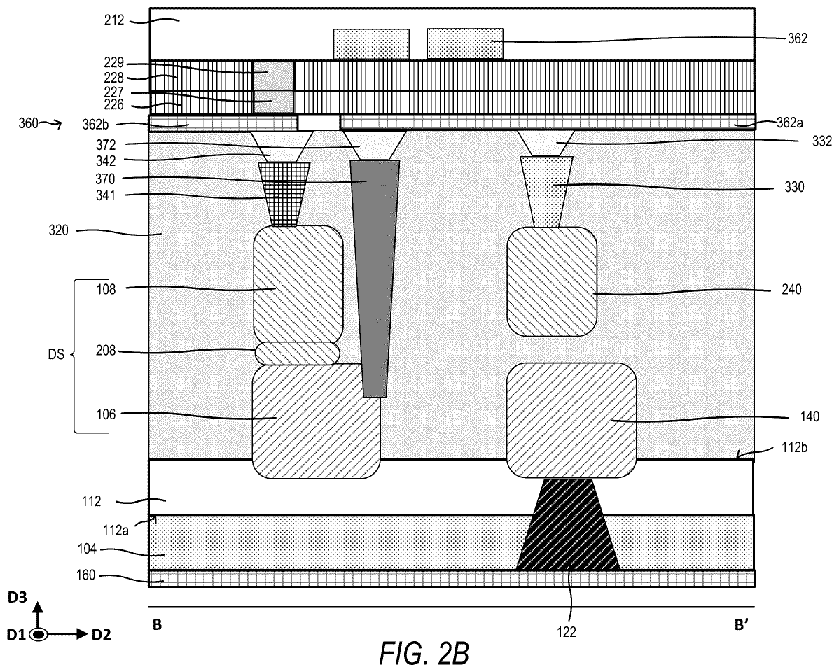

FIG. 1 is a layout of an integrated circuit device according to some embodiments. FIGS. 2A and 2B are cross-sectional views of an integrated circuit device 1 taken along the line A-A′ and the line B-B′, respectively, in FIG. 1 according to some embodiments. For simplicity in the drawings and in the description thereof, not all components are shown in each of the figures, and some components may be omitted from the drawings entirely.

Referring to FIGS. 1, 2A and 2B, the first integrated circuit device 1 may include a stacked structure 2 provided on a first substrate 112. In some embodiments, a plurality of stacked structures 2 may be provided. Each stacked structure 2 may include an upper transistor structure 200 and a lower transistor structure 100 that is provided between the first substrate 112 and the upper transistor structure 200. The upper transistor structure 200 may be stacked on the lower transistor structure 100, which may be on the first substrate 112.

The first substrate 112 may include a lower surface 112a and an upper surface 112b opposite the upper surface 112a. The lower surface 112a and the upper surface 112b may be parallel to each other. As used herein, a “lower” component on the first substrate 112 may refer to a first component that is closer to a lower surface 112a of the first substrate 112 than a second component on the first substrate 112. Similarly, an “upper” component may refer to a second component which may on the first substrate 112 and farther from the lower surface 112a of the first substrate 112 than the first component.

A semiconductor region 114 (e.g., a first semiconductor region 114a, a second semiconductor region 114b) may be provided on the first substrate 112. The semiconductor region 114 may extend in a first direction D1 (also referred to as a first horizontal direction) and may be spaced apart from other semiconductor regions 114 in a second direction D2 (also referred to as a second horizontal direction). As used herein, an element (e.g., an “element A”) said to extend in a direction (e.g., “direction X”), or similar language, may mean that the element extends longitudinally in the direction. The first direction D1 may be perpendicular to the second direction D2.

The semiconductor region 114 may protrude from the upper surface 112b of the first substrate 112 in a third direction D3 (also referred to as a vertical direction). The third direction D3 may be perpendicular to the first direction D1 and the second direction D2. In some embodiments, the third direction D3 may be perpendicular to the lower surface 112a and the upper surface 112b of the first substrate 112.

The first substrate 112 may include one or more semiconductor materials, for example, Si, Ge, SiGe, GaP, GaAs, SiC, SiGeC and/or InP or may include insulating material, for example, silicon oxide, silicon oxynitride, silicon nitride, silicon carbonitride, silicon boron nitride and/or a low-k material. In some embodiments, the first substrate 112 may be a bulk substrate (e.g., a bulk silicon substrate) or a semiconductor on insulator (SOI) substrate. For example, the first substrate 112 may be a silicon wafer or may be an insulating layer.

The semiconductor region 114 may be, for example, a portion of the first substrate 112 or may be a layer formed using the first substrate 112 as a seed layer through, for example, an epitaxial growth process. For example, the semiconductor region 114 may include semiconductor material(s), for example, Si, Ge, SiGe, GaP, GaAs, SiC, SiGeC and/or InP.

A trench isolation layer (not shown) may be provided on the first substrate 112. Semiconductor regions 114 adjacent to each other may be separated from each other by a portion of the trench isolation layer. The trench isolation layer may include an insulating material(s) (e.g., silicon oxide, silicon oxynitride, silicon nitride, silicon carbonitride and/or a low-k material). The low-k material may include, for example, fluorine-doped silicon oxide, organosilicate glass, carbon-doped oxide, porous silicon dioxide, porous organosilicate glass, spin-on organic polymeric dielectrics and/or spin-on silicon based polymeric dielectric. In some embodiments, a bottom insulating layer (not shown) may be formed between the first substrate 112 at least portions of the lower transistor structure 100.

The lower transistor structure 100 may include lower channel regions 120 that may be stacked on the first substrate 112 in the third direction D3 and may overlap each other in the third direction D3. As used herein, a first element and a second element may be said to overlap each other in a given direction if, as an example, at least one (straight) line can be drawn in the given direction that intersects both the first element and the second element. The lower channel regions 120 may be stacked on the semiconductor region (e.g., the semiconductor region 114). The lower channel regions 120 may include opposing side surfaces that are spaced apart from each other in the first direction D1, and the lower transistor structure 100 may include a pair of lower source/drain regions 140 respectively on those opposing side surfaces of the lower channel regions 120. The pair of lower source/drain regions 140 may contact those opposing side surfaces of the lower channel regions 120, respectively.

The lower transistor structure 100 may also include a lower gate structure 130 that may include a lower gate insulator 131 and a lower gate electrode 132. The lower gate electrode 132 may extend in the second direction D2 and may traverse one or more semiconductor regions 114. A portion of the lower channel regions 120 may surrounded by the lower gate electrode 132, and the lower gate insulator 131 may separate the lower channel regions 120 from the lower gate electrode 132. The lower channel regions 120 may extend through the lower gate electrode 132 in the first direction D1 and may contact the lower gate insulator 131.

The upper transistor structure 200 may include upper channel regions 220 that may be stacked on the first substrate 112 in the third direction D3 and may overlap each other in the third direction D3. The upper channel regions 220 may also overlap the lower channel regions 120 in the third direction D3. The upper channel regions 220 may include opposing side surfaces that are spaced apart from each other in the first direction D1, and the upper transistor structure 200 may include a pair of upper source/drain regions 240 respectively on those opposing side surfaces of the upper channel regions 220. The pair of upper source/drain regions 240 may contact those opposing side surfaces of the upper channel regions 220, respectively.

The upper transistor structure 200 may also include an upper gate structure 230 that may include an upper gate insulator 231 and an upper gate electrode 232. The upper gate electrode 232 may extend in the second direction D2 and may traverse the semiconductor region 114. A portion of the upper channel regions 220 may be surrounded by the upper gate electrode 232, and the upper gate insulator 231 may separate the upper channel regions 220 from the upper gate electrode 232. The upper channel regions 220 may extend through the upper gate electrode 232 in the first direction D1 and may contact the upper gate insulator 231.

The lower channel regions 120 and upper channel regions 220 may include, for example, semiconductor material(s) (e.g., Si, Ge, SiGe, GaP, GaAs, SiC, SiGeC and/or InP). In some embodiments, the lower channel regions 120 may include a material different from the upper channel regions 220. In some embodiments, each of the lower channel regions 120 and the upper channel regions 220 may be a nanosheet that may have a thickness in a range of from 1 nm to 100 nm in the third direction D3 or may be a nanowire that may have a circular cross-section with a diameter in a range of from 1 nm to 100 nm.

The lower gate insulator 131 and the upper gate insulators 231 may include, for example, a silicon oxide layer and/or a high-k material layer. The high-k material layer may include, for example, Al₂O₃, HfO₂, ZrO₂, HfZrO₄, TiO₂, Sc₂O₃ Y₂O₃, La₂O₃, Lu₂O₃, Nb₂O₅ and/or Ta₂O₅. The lower gate insulator 131 and upper gate insulator 231 may be a gate dielectric layer. The lower gate electrodes 132 and the upper gate electrodes 232 may include, for example, a metallic layer that includes, for example W, Al, Cu, Mo, Co and/or Ru and may additionally include work function layer(s) (e.g., a TiN layer, a TaN layer, a TiAl layer, a TiC layer, a TiAlC layer, a TiAlN layer and/or a WN layer).

In some embodiments, a lower insulating spacer, e.g., a lower gate spacer or a lower inner gate spacer (not shown) may be provided between and separate the lower gate structure 130 and the lower source/drain region 140. In some embodiments, an upper insulating spacer, e.g., an upper gate spacer or an upper inner gate spacer (not shown), may be provided between and separate the upper gate structure 230 and an upper source/drain region 240. Each of the lower insulating spacer and the upper insulating spacer may include, for example, silicon oxide, silicon oxynitride, silicon nitride, silicon carbonitride and/or a low-k material.

In some embodiments, the lower transistor structure 100 and the upper transistor structure 200 may have different conductivity types, and the stacked structure 2 including the lower transistor structure 100 and the upper transistor structure 200 may be a complementary metal-oxide-semiconductor (CMOS). In some embodiments, the lower source/drain regions 140 of the lower transistor structure 100 may have a first conductivity type (e.g., N-type conductivity), and the upper source/drain regions 240 of the upper transistor structure 200 may have a second conductivity type (e.g., P-type conductivity) that is opposite to the first conductivity type.

Still referring to FIGS. 1 and 2, the first integrated circuit device 1 may further include a middle isolation layer 300 that is between the lower transistor structure 100 and the upper transistor structure 200 in the third direction D3. The middle isolation layer 300 may provide isolation between the lower transistor structure 100 and the upper transistor structure 200. Although the middle isolation layer 300 is shown as a single layer, the present disclosure is not limited thereto. A source/drain isolation layer 310 may be provided between a lower source/drain region 140 of the lower transistor structure 100 and an upper source/drain region 240 of the upper transistor structure 200. In some embodiments, the middle isolation layer 300 and the source/drain isolation layer 310 may be provided as a single isolation layer.

In some embodiments, the first integrated circuit device 1 may further include additional insulating layers, such as an insulating layer 320. The additional insulating layers may be on one or more sides of the first integrated circuit device 1, or the lower transistor structure 100 or the upper transistor structure 200 thereof, e.g., in a first direction D1, second direction D2, and/or third direction D3.

Gate contacts 330 may be arranged to provide electrical connections to the gate electrodes 132/232. Source/drain contacts 340 may be arranged to provide electrical connections to the source/drain regions 140/240. Although the source/drain contacts 340 are shown as being connected to the upper transistor structure 200 in FIG. 2A, the present disclosure is not limited thereto, and source/drain contacts 340 may be connected with the lower source/drain regions 140 of the lower transistor structure 100. Similarly, although the gate contacts 330 are shown as being connected to the upper transistor structure 200 in FIG. 2A, the present disclosure is not limited thereto, and gate contacts 330 may be connected with the lower gate electrodes 132 of the lower transistor structure 100.

Although not shown in FIGS. 1 and 2A, it can be seen in FIG. 2B that one or more metal layers, including a first metal layer 360, may be provided above the source/drain contacts 340 and gate contacts 330. The one or more metal layers may be back end of line (BEOL) metal layers. Metal lines provided in the one or more metal layers may be electrically coupled to the source/drain contacts 340 and/or gate contacts 330. The one or more metal layers may include one or more metallic materials, such as, W, Al, Cu, Mo, Co and/or Ru.

The first integrated circuit device 1 may further include a backside interlayer (e.g., a backside interlayer dielectric) 104, a power contact 122, and a backside power rail 160. The backside interlayer 104 may include, for example, silicon oxide, silicon oxynitride, silicon nitride, silicon carbonitride and/or a low-k material.

The power contact 122 may be, at least partially, in the backside interlayer 104 and in the first substrate 112. In some embodiments, the power contact 122 may extend through the backside interlayer 104 and the first substrate 112 in the third direction D3, and the power contact 122 may be electrically connected (e.g., contact) the lower source/drain region 140 (e.g., a lower surface of the lower source/drain region 140), as illustrated in FIG. 2A. In some embodiments, the backside power rail 160 may be a first backside power rail, and additional backside power rails 160 may be provided and in electrical contact with lower source/drain regions 140 or upper source/drain regions 240.

As seen in FIG. 2B, on a side of the first integrated circuit device 1 opposite the one or more metal layers 360 from the first substrate 112, a first bonding oxide layer 226 may be provided, and a first metal via 227 may be formed therein. Additionally, a carrier substrate 212 may be provided. The carrier substrate 212 may be introduced during a formation of the backside interlayer 104, power contact 122, and backside power rail 160, in a manner described in greater detail below. The carrier substrate 212 may be bonded to the first bonding oxide layer 226 by way of a second bonding oxide layer 228. The second bonding oxide layer 228 may include a second metal via 229 therein. The first metal via 227 in the first bonding oxide layer 226 may be aligned vertically with the second metal via 229 in the second bonding oxide layer 228. The first metal via 227 and the second metal via 229 may be aligned vertically with a metal line provided in the one or more metal layers 360 and in electrical contact with the one or more metal layers 360.

An align key 364 may be in the carrier substrate 212 and used to align the first substrate 112 and the components thereupon with the carrier substrate 212 during a process in which the first bonding oxide layer 226 is bonded to the second bonding oxide layer 228. For example, the presence of the align key 364 may result in alignment of the first metal via 227 and the second metal via 229. The align key 364, first metal via 227, and second metal via 229 may each be formed of the one or more metallic materials, such as, W, Al, Cu, Mo, Co and/or Ru. In some embodiments, the align key 364, first metal via 227, and second metal via 229 may be formed of the same metallic material, with the understanding that the present disclosure is not limited thereto.

During semiconductor fabrication processes, processes using plasma may be used at one or more steps. For example, plasma induced charges may be captured on the one or more metal lines of the one or more metal layers 360, and the plasma induced charges may flow into gate dielectric layers (such as lower gate insulator 131 or upper gate insulator 231), resulting in potential breakdown of a gate dielectric layer. This accumulation of charge may be particularly problematic for the upper transistor structure 200, as the presence of the middle isolation layer 300 may act as a barrier for charges that accumulate in the upper gate structure 230 from discharging into e.g., the first substrate 112.

Accordingly, pursuant to some embodiments of the present inventive concepts, a discharging path may be provided between the carrier substrate 212 and the upper and lower transistor structures 100 and 200. The discharging path may include a diode structure DS. With reference to FIGS. 1 and 2B, the diode structure DS may be located adjacent to the stacked structure 2 in a horizontal direction (e.g., the second direction D2).

The diode structure DS may include a first semiconductor region 106 and a second semiconductor region 108, which may be a first diode region 106 and a second diode region 108, respectively. The first diode region 106 may be a lower diode region may have a conductivity type that is the same as the conductivity type of the lower source/drain region 140 (e.g., the first conductivity type). The second diode region 108 may be an upper diode region and may have a conductivity type that is the same as the conductivity type of the upper source/drain regions 240 (e.g., the second conductivity type). The first diode region 106 and the second diode region 108 may directly contact one another and form a junction (e.g., a P-N junction) therebetween. In some embodiments, the first diode region 106 and the second diode region 108 may be vertically stacked, where the second diode region 108 is on the first diode region 106 in the third (vertical) direction D3.

In some embodiments, a third diode region 208 may be between the first diode region 106 and the second diode region 108. The third semiconductor region 208 may be formed at the same time and via the same process as the first diode region 106 or the second diode region 108. In some embodiments, second diode region 108, the third diode region 208, and the first diode region 106 may collectively form a single diode.

In some embodiments, the first diode region 106 and/or the second diode region 108 may have the same or different dimensions in one or more directions as the lower source/drain region 140 and the upper source/drain regions 240. In some embodiments, the first diode region 106 and/or the second diode region 108 may have different dimensions in one or more directions than one or both of the lower source/drain regions 140 and the upper source/drain regions 240. At least one of the first diode region 106 and the second diode region 108 (or a portion thereof) may horizontally overlap with the lower source/drain region 140 and/or the upper source/drain region 240, e.g., in the second direction D2.

As seen in FIG. 2B, in some embodiments an upper surface of the lower source/drain region 140 of the lower transistor structure 100 and an upper surface of the second diode region 108 of the diode structure DS may be an equal distance from the first substrate 112. As seen in FIG. 2B, in some embodiments at least a lower surface of the first diode region 106 may be below an upper surface 112b of the first substrate 112. In some embodiments, the first diode region 106 may be a region or portion of the first substrate 112 that is doped or receives dopants to provide a selected conductivity type therein. For example, where the first semiconductor region 106 is a P-type layer, a region or portion of the first substrate 112 in which the diode structure DS is located may be provided with P-type dopants (e.g., boron (B), arsenic (Ar), phosphorous (P), and/or others).

In some embodiments, the first diode region 106 may be formed at a same time as the lower source/drain region 140, and the second diode region 108 may be formed at a same time as the upper source/drain region 240.

A diode contact 341 may be arranged to provide electrical connections to the diode structure DS. The diode contact 341 may be formed at the same time as the source/drain contacts 340 and may include a same material as the source/drain contacts 340. The diode contact 341 may contact an upper surface of the second diode region 108.

A discharge contact 370 may be formed which may have at least a lower surface that contacts (e.g., directly contacts) the first diode region 106. The discharge contact 370 may penetrate or extend through insulating layers or isolation layers, such as the insulating layer 320, the source/drain isolation layer 310, and/or the middle isolation layer 300. The discharge contact 370 may be in electrical contact with a first metal line 362a in the first metal layer 360 through a discharge via 372. The discharge via 372 may directly contact an upper surface or upper portion of the discharge contact 370. A gate via 332 may be formed which may electrically connect the first metal line 362a of the first metal layer 360 with a gate contact 330. A diode via 342 may be formed with may electrically connect a second metal line 362b of the first metal layer 360 with the diode contact 341. The first metal line 362a and the second metal line 362b may be electrically isolated from each other. The first metal via 227 and the second metal via 229 may be electrically connected to the second metal line 362b in the first metal layer 360. In some embodiments, one or more of the discharge via 372, diode via 342, and the gate via 332 are optional and a bottom or lower surface of the first metal layer 360 may directly contact upper surfaces of the discharge contact 370, diode contact 341, and/or the gate contact 330.

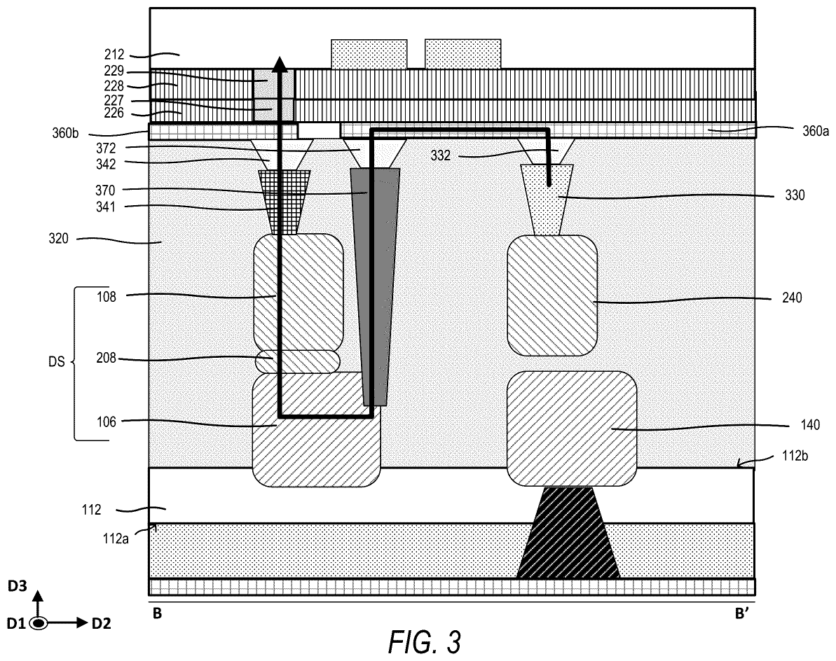

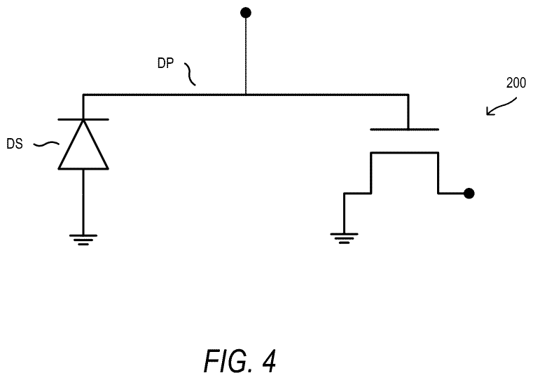

FIG. 3 is a schematic diagram showing that a discharging path DP between the upper transistor structure 200 of the stacked structure 2 and the carrier substrate 212 may be formed, using at least one metal layer (e.g., the first metal layer 360), which may be a BEOL metal layer and using a diode structure DS that is formed adjacent to the stacked structure 2. FIG. 4 is a circuit diagram of some components of the integrated circuit device of FIG. 3 according to some embodiments.

The discharging path DP may be an electrical path from the upper gate structure 230 or the upper gate electrode 232 of the upper transistor structure 200 (which may be a testing transistor) to the carrier substrate 212, and the discharging path DP may include (in order) the gate contact 330, the gate via 332, the first metal line 362a formed in the first metal layer 360, the discharge via 372, the discharge contact 370, the diode structure DS (the first diode region 106, the third diode region 208, and the second diode region 108), the diode contact 341, the diode via 342, the second metal line 362b formed in the first metal layer 360, the first metal via 227 in the first bonding oxide layer 226, the second metal via 229 in the second bonding oxide layer 228, and the carrier substrate 212. The discharging path may extend through the middle isolation layer 300, the source/drain isolation layer 310, and the insulating layer 320, as non-limiting examples.

It is noted that although the first and second metal lines 362a and 362b are described as part of the first metal layer 360, it is to be understood that any metal layer (e.g., M1, M2) on a common side of the first substrate 112 with the stacked structure 2 may be used as in the discharging path DP.

The discharging path DP may provide a path for charges (e.g., plasma induced charges) that may be captured in the upper gate structure 230 and/or the lower gate structure 130 to dissipate or discharge, rather than accumulate in portions of the upper transistor structure 200 or lower transistor structure 100, such as the upper channel regions 220 or lower channel regions 120, which may be floating regions. This may improve the performance and/or reliability of the integrated circuit device 1, for example because the upper gate insulator 231 may not be degraded or may not experience breakdown due to accumulated plasma induced charges.

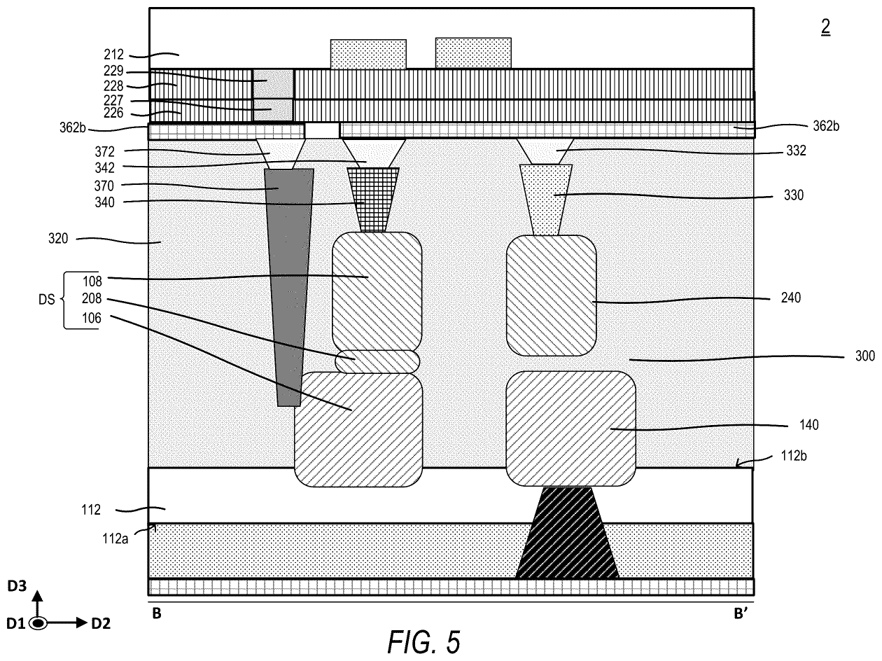

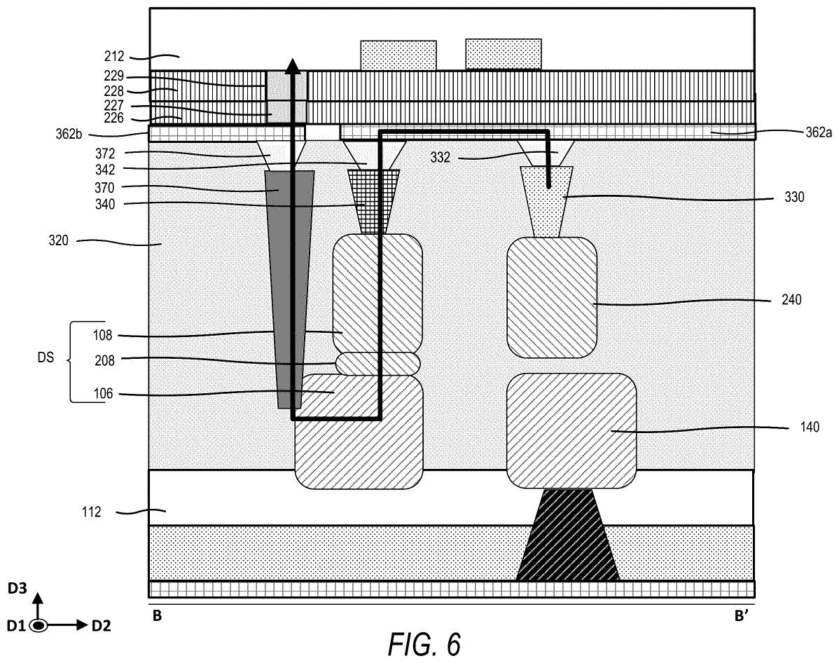

FIG. 5 is a cross-sectional view of an integrated circuit device 2 taken along the line B-B′ in FIG. 1 according to some embodiments, and FIG. 6 is a schematic diagram showing a discharging path of the integrated circuit device of FIG. 5. The integrated circuit device 2 may be similar to the integrated circuit 1 of FIGS. 1, 2A, and 2B, with the primary difference being that the discharging path through the diode structure DS may be reversed, with the second diode region 108 closer than the first diode region 106 to the gate contact 330 on the discharging path DP. The discharging path DP may be an electrical path from the upper gate structure 230 or the upper gate electrode 232 of the upper transistor structure 200 (which may be a testing transistor) to the carrier substrate 212, and the discharging path DP may include (in order) the gate contact 330, the gate via 332, the first metal line 362a formed in the first metal layer 360, the diode via 342, the diode contact 341, the diode structure DS (the second diode region 108, the third diode region 208, and the first diode region 106), the discharge contact 370, the discharge via 372, the second metal line 362b formed in the first metal layer 360, the first metal via 227 in the first bonding oxide layer 226, the second metal via 229 in the second bonding oxide layer 228, and the carrier substrate 212. The discharging path may extend through the middle isolation layer 300, the source/drain isolation layer 310, and the insulating layer 320, as non-limiting examples.

The structure of the integrated circuit device 1 may be used with testing transistors or devices of a first type (e.g., n-type MOSFETS) and the structure of the integrated circuit device 2 may be used with testing transistors or devices of a second type (e.g., p-type MOSFETS) with the understanding that the present disclosure is not limited thereto.

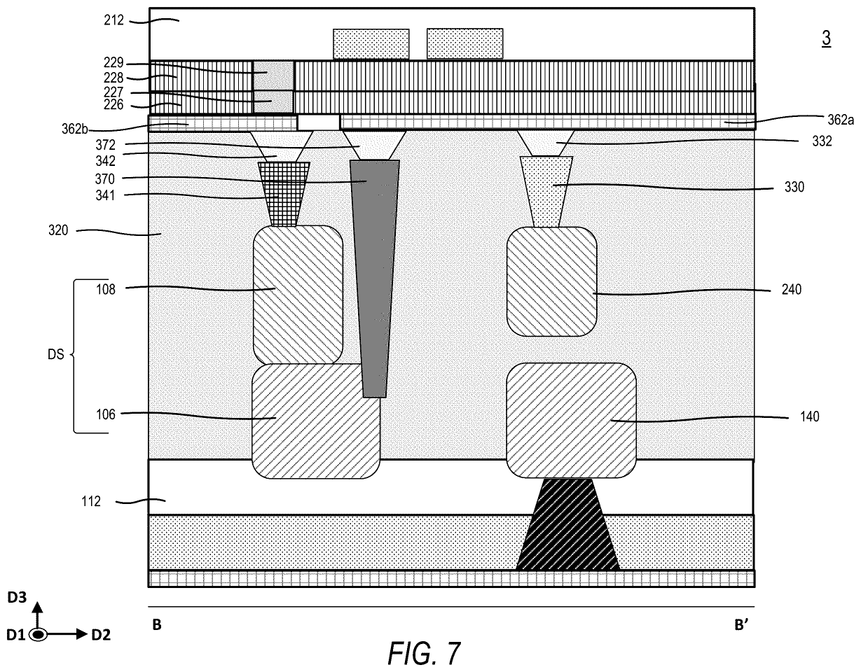

FIG. 7 is a cross-sectional view of an integrated circuit device 3 taken along the line B-B′ in FIG. 1 according to some embodiments. The integrated circuit device 3 may be similar to the integrated circuit 1 of FIGS. 1, 2A, and 2B, with the primary difference being that the third diode region 208 may not be formed, and the diode structure may include only the first diode region 106 and the second diode region 108. FIG. 5 also shows that in some embodiments, the lower surface of the second diode region 108 may be below an upper surface 112b of the first substrate 112. The integrated circuit device 1 of FIGS. 1, 2A, and 2B may be modified accordingly.

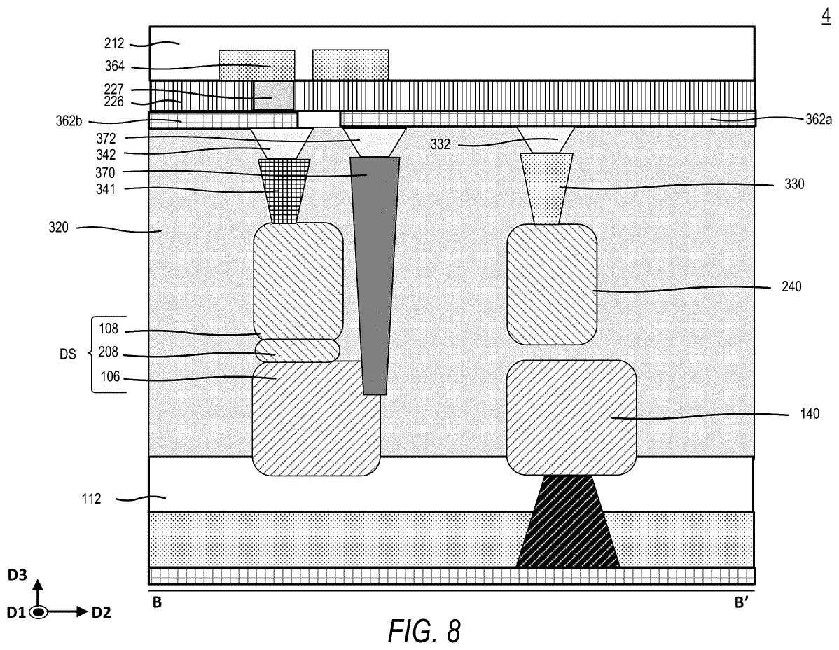

FIG. 8 is a cross-sectional view of an integrated circuit device 4 taken along the line B-B′ in FIG. 1 according to some embodiments. The integrated circuit device 4 may be similar to the integrated circuit 1 of FIGS. 1, 2A, and 2B, with the primary difference being that the second bonding oxide layer 228 and the second metal via 229 may not be present in some embodiments. Instead, the align key 364 may be used as part of providing a discharging path between the gate structures 130/230 and the carrier substrate 362. The first bonding oxide layer 226 may be bonded (e.g., directly bonded) to the carrier substrate through performing plasma ignition with the hydroxyl group on the Si substrate. The integrated circuit device 1 of FIGS. 1, 2A, and 2B, the integrated circuit device 2 of FIG. 5, and the integrated circuit device 3 of FIG. 7 may be modified accordingly.

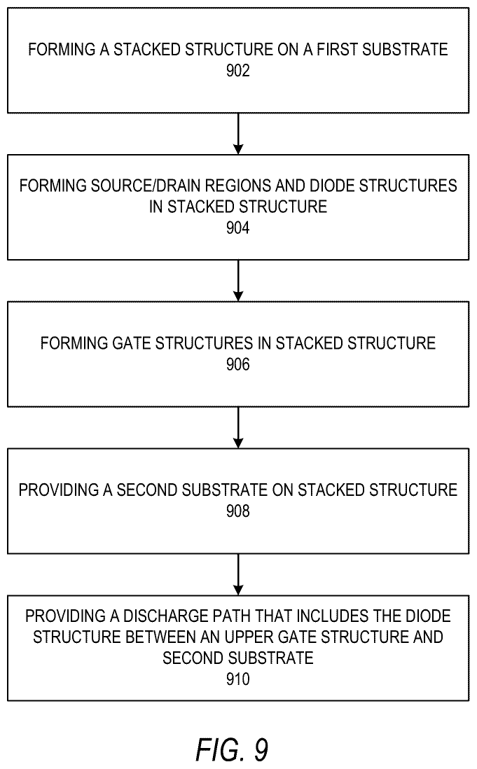

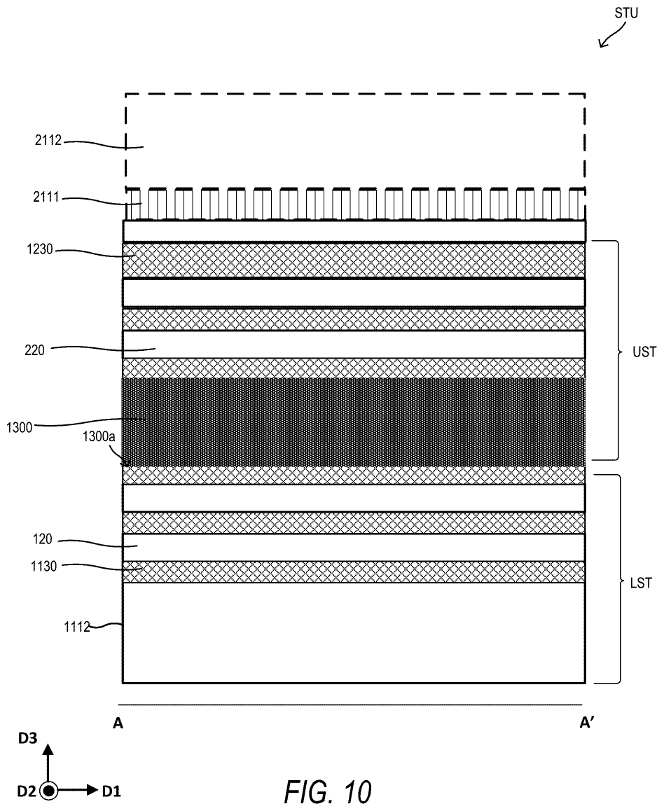

FIG. 9 is a flowchart showing operations in a method of forming an integrated circuit device according to some embodiments. FIGS. 10, 11, 12A, 12B, 13-16, 17A, 17B, 17C, 18, and 19 are cross-sectional views of intermediate steps of a method of forming the integrated circuit device of FIG. 1.

Referring to FIG. 9 and FIG. 10, a stack structure STU may be formed by one or more of various processes (block 902 of FIG. 9). For example, an upper stack portion UST may be formed by forming upper channel layers 220, upper sacrificial layers 1230 that are alternately stacked with the upper channel layers 220 and an insulator layer 1300 on an upper substrate 2112 and then performing an ion implantation process to form a separation layer 2111. The ion implantation process may implant ions (e.g., hydrogen ions) into a portion of the upper substrate 2112, and thus the separation layer 2111 may include those implanted ions. Alternatively, the upper stack portion UST may be formed by forming the separation layer 2111 through, for example, a deposition process on the upper substrate 2112, and then the upper channel layers 220, the upper sacrificial layers 1230 and the insulator layer 1300 may be formed on the separation layer 2111. The separation layer 2111 may include, for example, SiN, SiBCN, SiOCN, SiBN, SiCN, SiO and/or SiON.

A lower stack portion LST may be formed and may include a lower substrate 1112, and lower channel layers 120 and lower sacrificial layers 1130 stacked alternately with the lower channel layers 120 on the lower substrate 1112.

The lower sacrificial layers 1130 and the upper sacrificial layers 1230 may include a material having an etch selectivity with respect to the lower and upper channel layers 120 and 220. The lower and upper sacrificial layers 1130 and 1230 may include, for example, semiconductor material(s) (e.g., Si, Ge, SiGe, GaP, GaAs, SiC, SiGeC and/or InP). In some embodiments, the lower and upper sacrificial layers 1130 and 1230 may include a SiGe layer.

An upper surface of the insulator layer 1300a may be stacked on the uppermost layer 120/1130 of the lower stack portion LST. The upper substrate 2112 and the separation layer 2111 may then be removed, thereby forming the stack structure STU. For example, the separation layer 2111 may be removed by performing an annealing process to split the separation layer 2111 from the upper channel layers 220. In some embodiments, a dry etching process and/or a Chemical Mechanical Polishing (CMP) process may be performed to remove the upper substrate 2112 and the separation layer 2111, and the separation layer 2111 may be used as an etch stop layer while removing the upper substrate 2112.

In some embodiments, the lower stack portion LST may also include an insulator layer similar to the insulator layer 1300 of the upper stack portion UST, and the upper stack portion UST may be stacked on the insulator layer of the lower stack portion LST. In some embodiments, the lower stack portion LST may include an insulator layer similar to the insulator layer 1300 of the upper stack portion UST, and the insulator layer 1300 of the upper stack portion UST may be omitted, and the upper stack portion UST may be stacked on the insulator layer of the lower stack portion LST.

In some embodiments, the stack structure STU may be formed by providing a lower substrate 1112, and then alternately stacking the lower channel layers 120 and the lower sacrificial layers 1130 on the lower substrate 1112. The insulator layer 1300 may then be formed on the stack of lower channel layers 120 and the lower sacrificial layers 1130. Upper sacrificial layers 1230 and upper channel layers 220 may be alternately stacked on the insulator layer 1300, which may become the middle isolation layer 300. Thus, in some embodiments, the upper substrate 2112 and the separation layer 2111 may not be used in the formation of the stack structure STU.

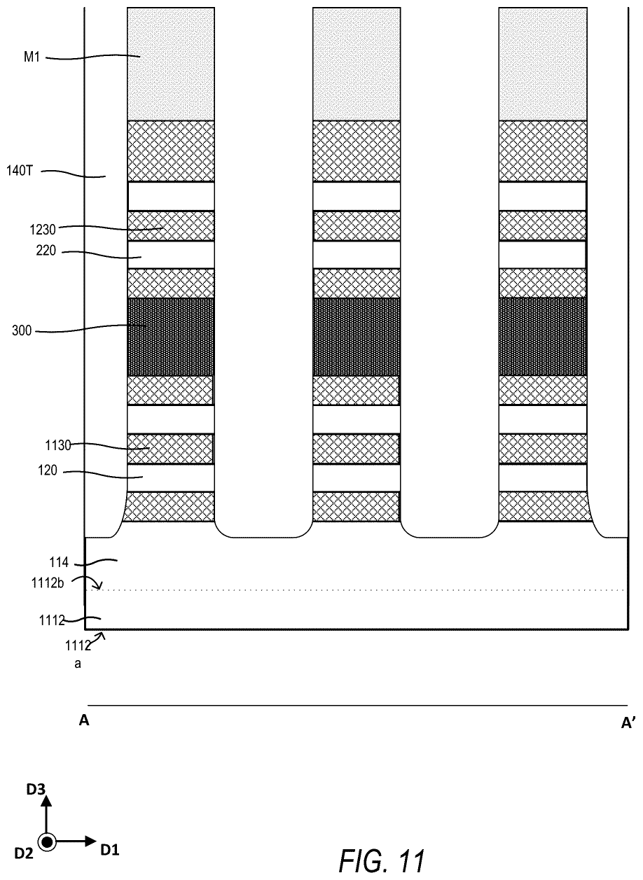

Referring to FIG. 11, trenches 140T may be formed in the stack structure STU. For example, a mask layer (not shown) may be formed and the stack structure STU may be etched using the mask layer as an etch mask until the lower substrate 1112 is exposed, thereby forming semiconductor regions. In some embodiments, diode trenches may be formed concurrently with the trenches 140T, which have different dimensions than the trenches 140T. For example, the diode trenches may extend further into the first substrate 112 from an upper surface 112b thereof than the trenches 140T.

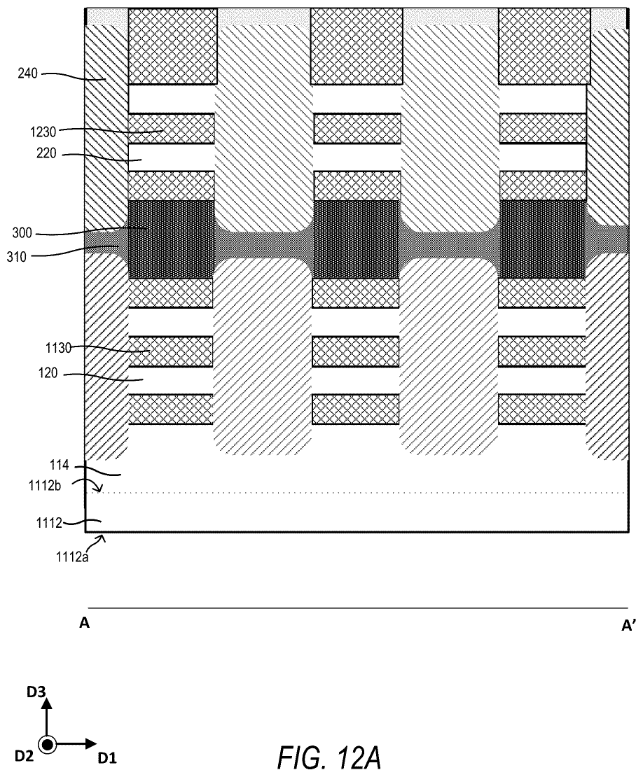

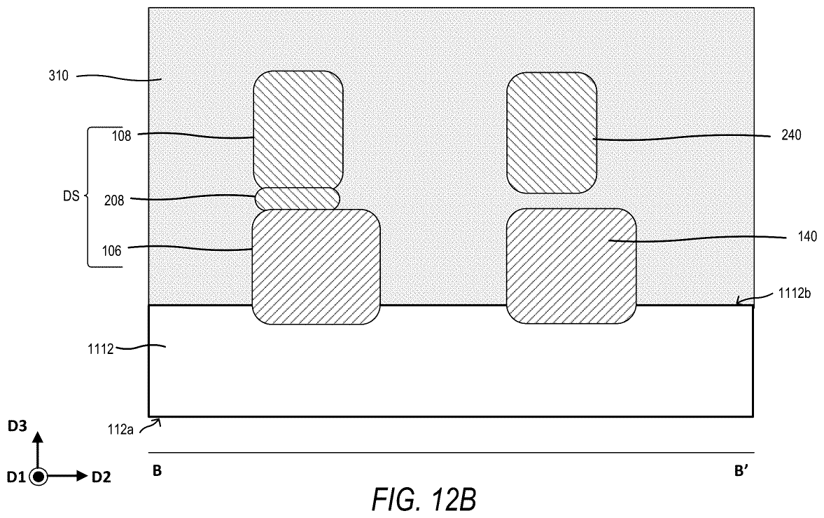

Referring to FIGS. 9, 12A, and 12B, lower source/drain regions 140 and upper source/drain regions 140 and the diode structures DS may be formed in the trenches DT (block 904 of FIG. 9).

For example, the lower source/drain regions 140 may be formed by an epitaxial growth process using the lower channel regions 120 as a seed layer, and the upper source/drain regions 240 may be formed by an epitaxial growth process using the upper channel regions 220 as a seed layer. In some embodiments, a source/drain insulator may be formed on the lower source/drain region 140 before forming the upper source/drain region 240.

The diode structure DS may include a first semiconductor region 106 and a second semiconductor region 108, which may be a first diode region 106 and a second diode region 108, respectively. The first diode region 106 may be a lower diode region may have a conductivity type that is the same as the conductivity type of the lower source/drain region 140 (e.g., the first conductivity type), and may be formed concurrently with the lower source/drain region 140. The second semiconductor region 108 may be an upper diode region and may have a conductivity type that is the same as the conductivity type of the upper source/drain regions 240 (e.g., the second conductivity type) and may be formed concurrently with the upper source/drain regions 240. The first diode region 106 and the second diode region 108 may directly contact one another and form a junction (e.g., a P-N junction) therebetween. In some embodiments, the first diode region 106 and the second diode region 108 may be vertically stacked, where the second diode region 108 is on the first diode region 106 in the third (vertical) direction D3.

When the lower source/drain regions 140 and the first diode region 106 are formed as p-type regions, a p-type impurity source gas, such as diborane (B₂H₆) gas, may be introduced during the epitaxial growth process thereof (e.g., during a selective epitaxial growth process (SEG)) to form the lower source/drain regions 140 and the first diode region 106 as doped with p-type impurities. When the upper source/drain regions 240 and the second diode region 108 are formed as n-type regions, a n-type impurity source gas such as POCl₃, P₂O₅, or the like, may be introduced during the epitaxial growth process thereof to form the upper source/drain regions 240 and the second diode region 108 as doped with n-type impurities. The present disclosure is not limited to forming the lower and upper source/drain regions 140, 240 and first and second diode regions 106, 108 using impurity source gases during epitaxial growth processes. In some embodiments, the lower source/drain regions 140 and the first diode region 106 may be formed as n-type regions (e.g., using an n-type impurity source gas), and the upper source/drain regions 240 and the second diode region 108 may be formed as p-type regions (e.g., using a p-type impurity source gas).

A source/drain isolation layer 310 may be formed in the trenches 140T and may be on and may surround the lower source/drain regions 140, first diode regions 106, upper source/drain regions 240, and second diode regions 108.

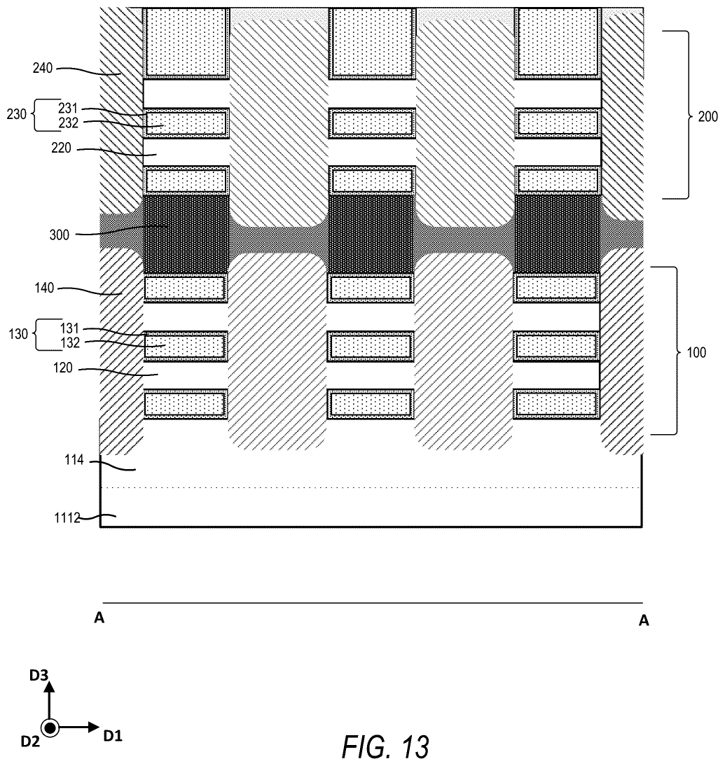

Referring to FIGS. 9 and 13, lower and upper gate structures 130 and 230 may be formed (block 906 of FIG. 9). Referring to FIG. 13, the upper sacrificial pattern 1230 and the lower sacrificial pattern 1130 may be removed to expose the lower and upper channel regions 120 and 220, and then lower and upper gate insulators 131 and 231 may be formed on the lower and upper channel regions 120 and 220, respectively. The lower gate insulator 131 may define a first opening and the upper gate insulator 231 may define a second opening. A lower gate electrode 132 may be formed in the first opening, and an upper gate electrode 232 may be formed in the second opening.

The lower gate structure 130, lower channel regions 120, and lower source/drain regions 140 may form a lower transistor structure 100. The upper gate structure 230, upper channel regions 220, and upper source/drain regions 240 may form an upper transistor structure 200.

Referring to FIGS. 9, 14, 15, and 16, portions of a discharging path DP may be formed on the substrate 1112 (block 910 of FIG. 9). The discharging path DP may include the diode structure DS. The discharging path DP may extend through the middle isolation layer 300 and/or the source/drain isolation layer 310.

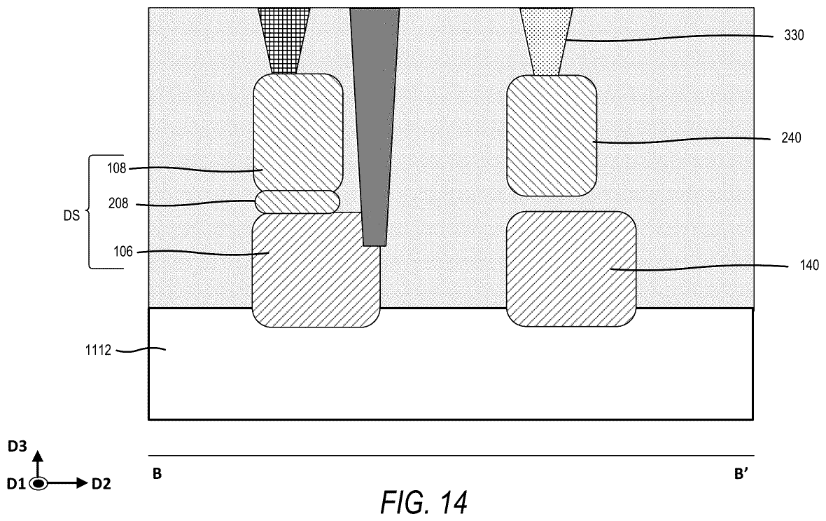

Referring to FIG. 14, a mask layer (not shown) may be formed on an upper surface of the insulating layer 320. Gate contact trenches, diode contact trenches, source/drain contact trenches, and discharge contact trenches may be formed in the insulating layer 320, and gate contacts 330 may be formed in the gate contact trenches, diode contacts 341 may be formed in the diode contact trenches, source/drain contacts 340 may be formed in the source/drain contact trenches, and discharge contacts 370 may be formed in the discharge contact trenches. The mask layer may then be removed.

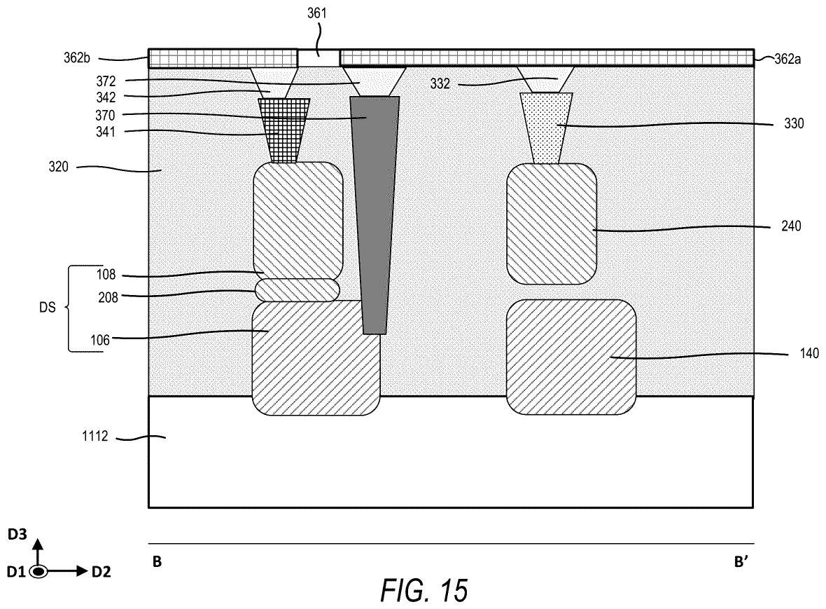

Referring to FIG. 15, gate vias 322 may be formed on the gate contacts 330, diode vias 342 may be formed on the diode contacts 341, and discharge vias 372 may be formed on the discharge contacts 370. One or more metal layers, including a first metal layer 360, may be formed on the gate vias 322 and discharge vias 372. For example, a first metal line 362a and a second metal line 362b may be formed in the first metal layer 360. The first metal line 362a and the second metal line 362b may be electrically isolated from each other by an isolation layer 361. The one or more metal layers may be back end of line (BEOL) metal layers.

Referring to FIG. 16, the first bonding oxide layer 226 may be provided on the one or more metal layers. A first metal via 227 may be formed in the first bonding oxide layer 226. For example, a mask may be formed on the first bonding oxide layer 226, and the first bonding oxide layer 226 may be etched to form a via trench, and the first metal via 227 may be formed to fill the via trench. The result of the operations of FIG. 10-16 may be intermediate structure 1a of FIG. 16.

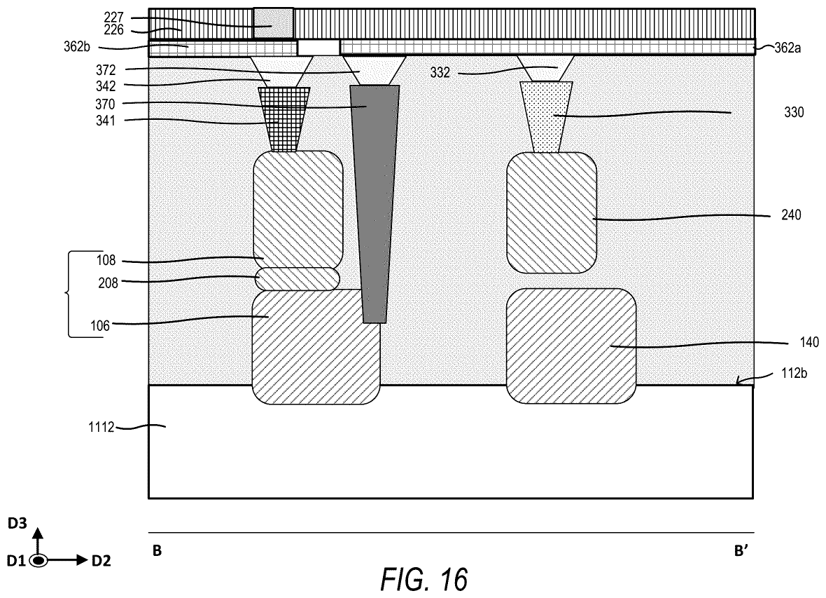

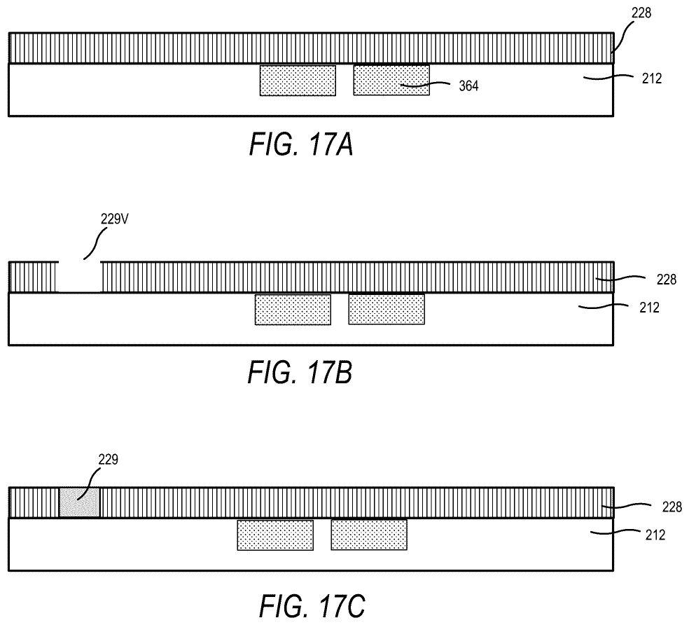

Referring to FIGS. 9, 17A-C and 18, a second substrate 212 may be provided on a side of the upper transistor structure 200 and lower transistor structure 100 opposite from the lower substrate 1112 (block 908 of FIG. 9). The second substrate 212 may be the carrier substrate 212 of FIGS. 1, 2A. and 2B, and may include an align key 364 therein. Referring to FIG. 17A, in some embodiments, the second substrate 212 may be prepared by having a second bonding oxide layer 228 applied thereto. Referring to FIG. 17B, a trench 229V may be formed in the second bonding oxide layer 228, and referring to FIG. 17C, the second metal via 229 may be formed in the trench. In some embodiments, and with reference to FIG. 8, the second bonding oxide layer 228 and the second metal via 229 may be omitted from the second substrate.

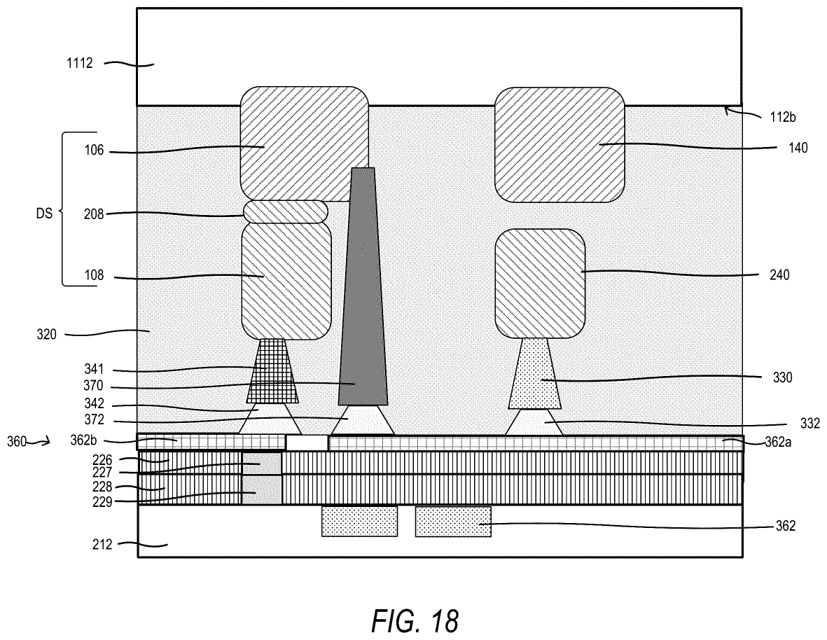

Referring to FIG. 18, the intermediate structure 1a of FIG. 16 may be flipped and bonded to the second substrate 212 or the second bonding oxide layer 228 applied thereto. The align key 364 may be used to align the intermediate structure 1a with the second substrate 212.

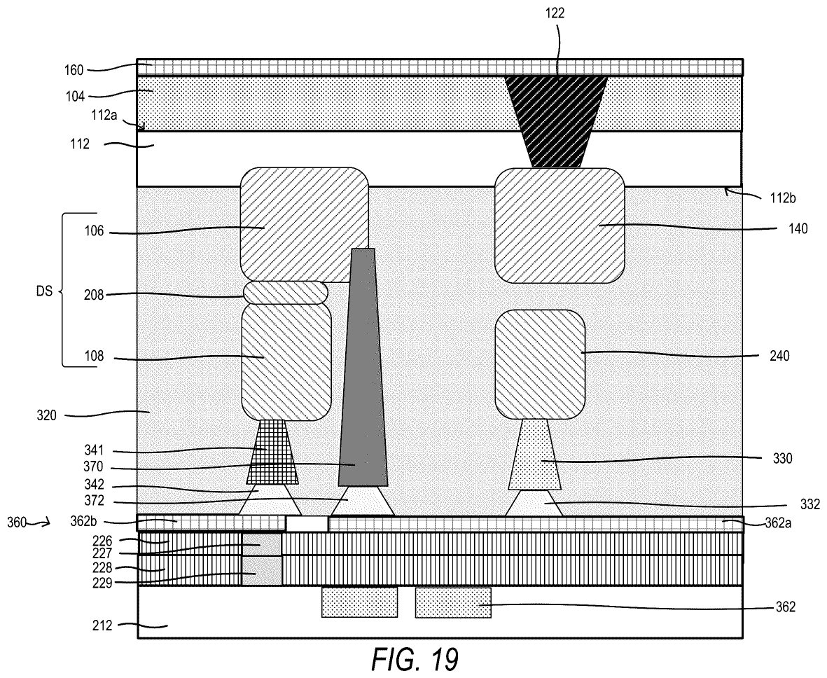

Referring to FIG. 19, the back side power distribution network may be formed. First, the lower substrate 1112 may be thinned, resulting in the first substrate 112. Then, the backside interlayer 104 may be formed on the lower surface 112a of the first substrate. The power contact 122 may be formed, and may extend through the backside interlayer 104 and the first substrate 112, and may contact the lower source/drain region 140. The backside power rail 160 may be formed on the backside interlayer 104.

Referring to FIGS. 19 and 3, a discharging path DP may be provided from the upper gate structure 230 or the upper gate electrode 232 of the upper transistor structure 200 (which may be a testing transistor) to the carrier substrate 212 (block 910 of FIG. 9), and the discharging path DP may include (in order) the gate contact 330, the gate via 332, the first metal line 362a formed in the first metal layer 360, the discharge via 372, the discharge contact 370, the diode structure DS (the first diode region 106, the third diode region 208, and the second diode region 108), the diode contact 341, the diode via 342, the second metal line 362b formed in the first metal layer 360, the first metal via 227 in the first bonding oxide layer 226, the second metal via 229 in the second bonding oxide layer 228, and the carrier substrate 212. The discharging path may extend through the middle isolation layer 300, the source/drain isolation layer 310, and the insulating layer 320, as non-limiting examples.

Some examples of embodiments are described herein with reference to the accompanying drawings. Many different forms and embodiments are possible without deviating from the scope of the present invention. Accordingly, the present invention should not be construed as limited to the example embodiments set forth herein. Rather, these example embodiments are provided so that this disclosure will be thorough and complete and will convey the scope of the present invention to those skilled in the art. In the drawings, the sizes and relative sizes of layers and regions may be exaggerated for clarity. Like reference numbers refer to like elements throughout.

Example embodiments of the present invention are described herein with reference to cross-sectional views that are schematic illustrations of idealized embodiments and intermediate structures of example embodiments. As such, variations from the shapes of the illustrations as a result, for example, of manufacturing techniques and/or tolerances, are to be expected. Thus, example embodiments of the present invention should not be construed as limited to the particular shapes illustrated herein but include deviations in shapes that result, for example, from manufacturing, unless the context clearly indicates otherwise.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of the stated features, steps, operations, elements and/or components, but do not preclude the presence or addition of one or more other features, steps, operations, elements, components and/or groups thereof. As used herein the term “and/or” includes any and all combinations of one or more of the associated listed items.

It will be understood that although the terms first, second, etc. may be used herein to describe various elements, these elements should not be limited by these terms. These terms are only used to distinguish one element from another. Thus, a first element could be termed a second element without departing from the scope of the present invention.

The above-disclosed subject matter is to be considered illustrative, and not restrictive, and the appended claims are intended to cover all such modifications, enhancements, and other embodiments, which fall within the scope of the invention. Thus, to the maximum extent allowed by law, the scope is to be determined by the broadest permissible interpretation of the following claims and their equivalents and shall not be restricted or limited by the foregoing detailed description.

What is claimed is:

1. An integrated circuit device comprising:
a first substrate;
a first transistor structure on the first substrate;
a second transistor structure stacked in a vertical direction on the first transistor structure;
a second substrate stacked in a vertical direction on the second transistor structure;
an isolation layer between the first transistor structure and the second transistor structure in the vertical direction; and
a discharging path between a gate electrode of the second transistor structure and the second substrate, the discharging path including a diode structure on the first substrate.

2. The integrated circuit device of claim 1, wherein the discharging path extends through the isolation layer.

3. The integrated circuit device of claim 1, wherein the diode structure is adjacent to the first transistor structure horizontally.

4. The integrated circuit device of claim 1, further comprising a back-end-of-line (BEOL) metal layer, wherein the discharging path comprises the BEOL metal layer.

5. The integrated circuit device of claim 1, wherein the first transistor structure comprises a first source/drain region having a first conductivity type, and wherein the second transistor structure comprises a second source/drain region having a second conductivity type that is opposite from the first conductivity type.

6. The integrated circuit device of claim 5, wherein the diode structure comprises a first diode region having the first conductivity type and a second diode region that has the second conductivity type.

7. The integrated circuit device of claim 6, further comprising a discharge contact that directly contacts the first diode region.

8. The integrated circuit device of claim 6, further comprising a discharge contact that directly contacts the second diode region.

9. The integrated circuit device of claim 6, wherein the second diode region directly contacts the first diode region.

10. The integrated circuit device of claim 6, further comprising a third diode region between the first diode region and the second diode region in the vertical direction.

11. The integrated circuit device of claim 1, further comprising at least one bonding oxide layer between the second transistor structure and the second substrate, with each at least one bonding oxide layer comprising a metal via therein,
wherein the discharging path includes the metal via included in each of the at least one bonding oxide layers.

12. The integrated circuit device of claim 1, wherein the discharging path includes a metal align key.

13. An integrated circuit device comprising:
a first substrate;
a stacked structure comprising:
a first transistor structure on the first substrate and comprising a first source/drain region having a first conductivity type; and
a second transistor structure stacked in a vertical direction on the first transistor structure, the second transistor structure comprising a second source/drain region having a second conductivity type that is opposite from the first conductivity type;
an isolation layer between the first transistor structure and the second transistor structure in the vertical direction;
a second substrate on an opposite side of the stacked structure from the first substrate; and
a discharging path between a gate electrode of the second transistor structure and the second substrate, the discharging path comprising a diode structure.

14. The integrated circuit device of claim 13, wherein the discharging path comprises a back-end-of-line (BEOL) metal layer.

15. The integrated circuit device of claim 13, further comprising at least one bonding oxide layer between the stacked structure and the second substrate, with each at least one bonding oxide layer comprising a metal via therein,
wherein the discharging path includes the metal via included in each of the at least one bonding oxide layers.

16. A method of forming an integrated circuit device, the method comprising:
forming a stacked structure on a first substrate, the stacked structure comprising lower channel layers, upper channel layers, and an isolation layer between the lower and upper channel layers;
forming source/drain regions in the stacked structure, the source/drain regions comprising lower source/drain regions and upper source/drain regions;
forming a diode structure in the stacked structure, the diode structure including a first diode region and a second diode region;
forming gate structures in the stacked structure, the gate structures comprising lower gate structures and upper gate structures;
providing a second substrate on an opposite side of the stacked structure from the first substrate; and
providing a discharging path between an upper gate structure and the second substrate, the discharging path including the diode structure.

17. The method of claim 16, further comprising forming a back-end-of-line (BEOL) metal layer, wherein the discharging path comprises the BEOL metal layer.

18. The method of claim 16, the lower source/drain regions have a first conductivity type, and the upper source/drain regions have a second conductivity type that is opposite from the first conductivity type.

19. The method of claim 18, wherein the first diode region has the first conductivity type and the second diode region has the second conductivity type.

20. The method of claim 16, wherein the discharging path extends through the isolation layer.
